(19) United States
(12) Patent Application Publication
(10) Pub. No.: US 2007/0267737 A1
(43) Pub. Date: Nov. 22, 2007

(54) PACKAGED DEVICES AND METHODS FOR FORMING PACKAGED DEVICES

(75) Inventors: Hsien-Wei Chen, Sinying City (TW); Hsueh-Chung Chen, Yonghe City (TW); Yi-Lung Cheng, Taipei County (TW)

Correspondence Address: DUANE MORRIS LLP;IP DEPARTMENT (TSMC), 30 SOUTH 17TH STREET, PHILADELPHIA, PA, 19103-4196, US

(73) Assignee: Taiwan Semiconductor Manufacturing Co., Ltd., Hsin-Chu (TW)

(21) Appl. No.: 11/383,922

(22) Filed: May 17, 2006

(51) Int. Cl. H01L 23/15

(52) U.S. Cl. 257/705

(57) ABSTRACT

Packaged devices and methods of forming packaged devices are provided. At least one device is disposed on a substrate. The material layer encapsulates the device and covers at least a portion of the substrate, wherein the material layer comprises at least a first portion adjacent to the device and a second portion over the first portion. The second portion has a thermal conductivity higher than a thermal conductivity of the first portion.

### BACKGROUND OF THE INVENTION

1. Field of the Invention

The present invention relates to packaged semiconductor devices and methods for forming semiconductor packages.

2. Description of the Related Art

Various device packaging methods and structures have been proposed in semiconductor industry to protect semiconductor chips sawed from processed wafers. The packaged device protects the semiconductor devices from particles, moisture, charges or other undesired forces from the outside environment, thereby improving the reliability and operation of the devices.

FIG. 1 shows a cross-sectional view of a prior art packaged device. The packaged device comprises a substrate 100, a device 110, i.e., a semiconductor die or chip, and a protective epoxy layer 130. The device 110 is disposed on the substrate 100 and electrically coupled to the substrate 100 through gold wires 120. The epoxy layer 130 covers the device 110 and dissipates heat generated from the operation of the device 110 to a heatspreader layer (not shown) thereon.

Dissipation of heat generated from currents flowing on the top surface of the device 110 is very essential. If not efficiently dissipated, heat accumulated on the top surface of the device can affect the electrical performance of the device 110. For example, a central processing unit (CPU) consumes electrical power of about 40 Watts. Without efficient heat dissipation, much of the heat generated by the operation of the CPU will accumulate thereon, potentially shortening the lifespan of the device 110. The heat dissipation efficiency becomes worse as dimensions of the packaged semiconductor device are reduced. Furthermore, the use of low dielectric constant materials in the device 110 can worsen the overall heat dissipation efficiency of the device due to their low thermal conductivity, though they may enhance the operational speed of the device 110.

In order to address the heat dissipation issues described above, an external heatspreader layer and/or a fan has been used to dissipate the heat generated by the device 110. Such a heatspreader layer or fan, however, does not form a part of the packaged device structure, making its operation inefficient.

By way of background, U.S. Patent Publication No. 2004/0041279 discloses a packaged electronic device having an improved adhesive layer for attaching a die to a substrate.

U.S. Patent Publication No. 2005/0222300 provides a description of encapsulating epoxy resin composition.

From the foregoing, improved package structures to efficiently dissipate accumulated heat from a semiconductor device and methods of forming such structures are still desired.

### SUMMARY OF THE INVENTION

According to some exemplary embodiments, a packaged device comprises a device on a substrate, and a material layer. At least one device is disposed on a substrate. The material layer encapsulates the device and covers at least a portion of the substrate, wherein the material layer comprises at least a first portion adjacent to the device and a second portion over the first portion. The second portion has a thermal conductivity higher than a thermal conductivity of the first portion.

The above and other features of the present invention will be better understood from the following detailed description of the preferred embodiments of the invention that is provided in connection with the accompanying drawings.

### BRIEF DESCRIPTION OF THE DRAWINGS

Following are brief descriptions of exemplary drawings. They are mere exemplary embodiments and the scope of the present invention should not be limited thereto.

FIG. 1 is a drawing showing a cross-sectional view of a prior art packaged device.

FIGS. 2A and 2B are schematic cross-sectional drawings showing an exemplary process of forming a packaged device according to an embodiment.

FIG. 3 is a schematic cross-sectional view of a packaged device according to another exemplary embodiment.

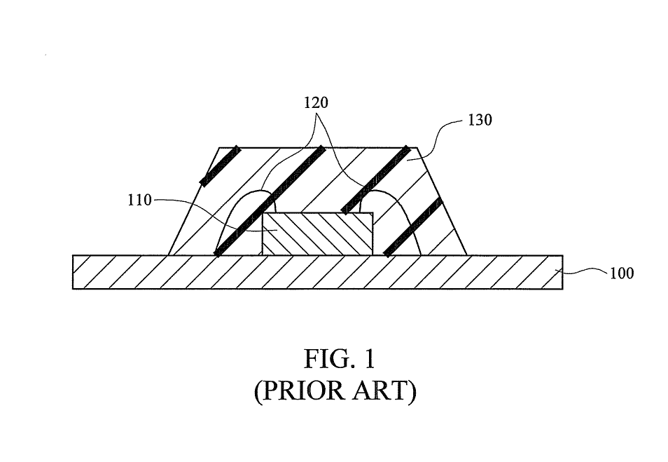

### DESCRIPTION OF THE PREFERRED EMBODIMENT

This description of the exemplary embodiments is intended to be read in connection with the accompanying drawings, which are to be considered part of the entire written description. In the description, relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation.

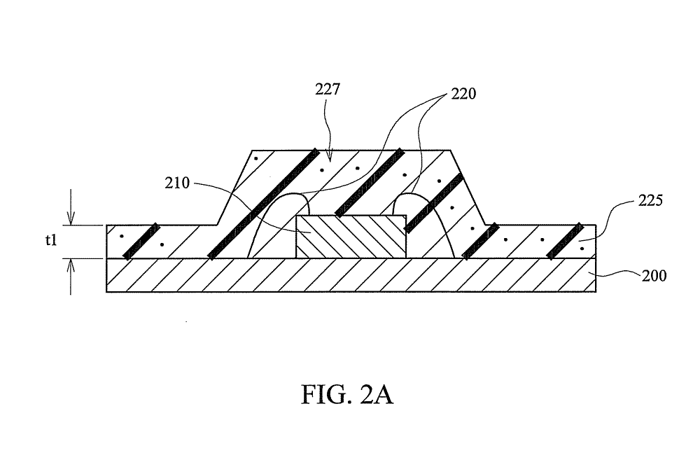

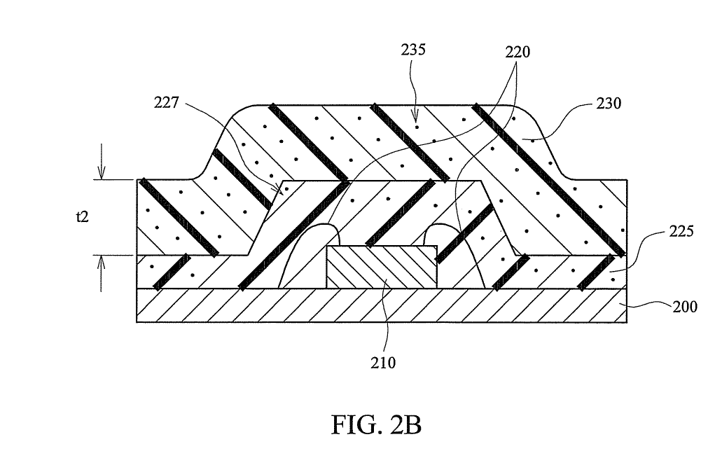

FIG. 2A is a schematic cross-sectional view of a semiconductor device disposed on a substrate and encapsulated by a first material layer according to an exemplary embodiment. In embodiments, the substrate 200 can be, for example, a silicon substrate, a III-V compound substrate, a glass substrate, a printed circuit board (PCB) or any other substrate similar thereto.

Although only one device 210 is shown, more than one device can be provided on the substrate 200. The device 210 can be a semiconductor chip, such as memory chip, a central processing unit (CPU), a logic circuit, an application-specific integrated circuit (ASIC), a laser diode, a light emitting diode or other semiconductor devices. In some embodiments, the device 210 is electrically coupled to the substrate 200 by a wire-bonding process, a flip-chip process or other processes that are adapted to electrically couple the device 210 to the substrate 200. The device 210 may also be bonded at least in part to the substrate 200 by a conductive or non-conductive adhesive. In the illustrated embodiment, the device 210 is electrically coupled to the substrate 200 with conductive wires 220 by a wire-bonding process. In the wire-bonding process, bonding pads (not shown) on the device 210 are attached to the substrate 200 through the conductive wires 220 by the use of a bonding machine (not shown). The conductive wires 220 are metal wires in some embodiments. In embodiments, the conductive wires 220 comprise gold (Au), copper (Cu), aluminum (Al), Al/Cu, alloy or other metallic materials that are suitable for the wire-bonding process.

A first material layer 225 encapsulates the device 210. The first material layer 225 covers the sidewalls and top surface of the device 210. In some embodiments, the first material layer 225 also covers at least a portion of the top surface of the substrate 200. In this embodiment, the first material layer 225 also covers the conductive wires 220. The first material layer 225 has a thickness “t1” from about 10 μm to about 200 μm as shown in FIG. 2A.

The first material layer 225 preferably comprises a thermalset polymer with a glass transition temperature (Tg) higher than about 200° C., such as polyimide, epoxy, Acrylonitrile-Butadiene-Styrene Terpolymer (ABS), Poly(methyl methacrylate) (PMMA), Polycarbonates (PC), Polyethylene terephthalate (PET), Polybutylece terephthalate (PBT), poly(etheretherketone) (PEEK), polyvinyl chloride (PVC) or other materials similar thereto. In one preferred embodiment, the first material layer 225 comprises epoxy.

In some embodiments, the first material layer 225, particularly when comprising epoxy, further comprises conductive fillers 227, such as metal powders, ceramic fillers, inorganic nanocomposites or other dopants or additives that are adapted to enhance the thermal conductivity or other characteristics of the first material layer 225. In some embodiments, the conductive fillers 227 are provided at such a level that the device 210 is at least somewhat electrically isolated from subsequent layers formed on or over the first material layer 225. “Metal powders” as used herein comprise metallic elements, such as aluminum, copper, iron or other conductive element. “Ceramic fillers” comprise silica, quartz, boron nitride, aluminum nitride or other material with electrical properties similar thereto. “Inorganic nanocomposites” comprise laminar clay particles or nanotubes. Metal powders, ceramic fillers, and inorganic nanocomposites can be added into the raw material (not shown) of the first material layer 225 by adding conductive fillers 235 shown in FIG. 2B within the raw material and then blending them. The raw material is then spin-coated or molded over the substrate 200 and the device 210. The coated substrate 200 and the device 210 with the first material layer 225 are then cured in a furnace or oven to remove moisture therein.

Tables I-III below show relations between dopant/additive concentrations within an epoxy matrix and thermal conductivity, wherein “W” represents Watt, “m” represents meter and “K” represents temperature in Kelvin.

TABLE I

| Additive | Alumina | | | | | | |
|---|---|---|---|---|---|---|---|
| Vol. % | 0 | 11.55 | 22.17 | 35.33 | 44.34 | 61.66 | 77.83 |
| Thermal | 0.14 | 0.186 | 0.22 | 0.43 | 0.65 | 1.22 | 2.02 |
| conductivity | | | | | | | |
| (W/mK) | | | | | | | |

TABLE II

| Additive | Silicia | | | | | | |
|---|---|---|---|---|---|---|---|
| Vol. % | 0 | 12.20 | 24.39 | 36.59 | 48.78 | 60.98 | 73.17 |
| Thermal conductivity | 0.18 | 0.26 | 0.31 | 0.4 | 0.54 | 0.67 | 0.85 |
| (W/mK) | | | | | | | |

TABLE III

| Additive | Quartz | | | | | | |
|---|---|---|---|---|---|---|---|
| Vol. % | 0 | 12.20 | 24.39 | 36.59 | 48.78 | 60.98 | 73.17 |
| Thermal conductivity | 0.18 | 0.26 | 0.45 | 0.72 | 1.07 | 1.61 | 2.28 |
| (W/mK) | | | | | | | |

From Tables I-III, it can be seen that the thermal conductivities of the epoxy matrix rise with increases in dopant concentrations of alumina, silica or quartz. Those skilled in the art will be able to modify the dopant concentrations to obtain the desired thermal conductivities of the material layer. Methods to measure the dopant concentrations and thermal conductivities are well known and easily accessible to the artisans in this field and, therefore, detailed descriptions are not provided. In some preferred embodiments, the first material layer 225 has a thermal conductivity less than or equal to about 0.3 W/mK and corresponding to an acceptable dopant concentration in order to avoid electrical short between the conductive wires 220.

In other embodiments, the first material layer 225 comprises a material with electron conjugation, such as Poly(p-phenylene vinylene) (PPV). The first material layer 225 with electron conjugation has an inherent thermal conductivity less than or equal to about 0.3 W/mK.

FIG. 2B is a schematic cross-sectional view of a semiconductor device 210 on a substrate 200 encapsulated by a second material layer 230 formed over the first material layer 225 according to an exemplary embodiment. The second material layer 230 is formed over the first material layer 225, and encapsulates the device 210. The second material layer 230 covers the sidewalls and top surface of the device 210 as well as the first material layer 225. In some embodiments, the second material layer 230 also covers at least a portion of the substrate 200. In this embodiment, the second material layer 230 also covers the conductive wires 220. The second material layer 230 has a thickness t2 of about 0.3 mm to about 2.0 mm as shown in FIG. 2B.

The second material layer 230 also preferably comprises a thermalset polymer with a glass transition temperature (Tg) higher than about 200 □, such as polyimide, epoxy, Acrylonitrile-Butadiene-Styrene Terpolymer (ABS), Poly(methyl methacrylate) (PMMA), Polycarbonates (PC), Polyethylene terephthalate (PET), Polybutylece terephthalate (PBT), poly(etheretherketone) (PEEK), polyvinyl chloride (PVC) or other materials similar thereto. The first material layer 225 and the second material layer 230 can comprise the same or different matrixes. In one embodiment, the matrixes of the first material layer 225 and the second material layer 230 both comprise epoxy.

In some embodiments, the second material layer 230 further comprises conductive fillers 235, such as metal powders, ceramic fillers, inorganic nanocomposites or other dopants which are adapted to enhance the thermal conductivity of the second material layer 230, as described above in connection with the first material layer 225. Metal powders, ceramic fillers, and inorganic nanocomposites can be added into the raw material (not shown) of the second material layer 230 by a blending process. The raw material of the second material layer 230 is then spin-coated or molded over the first material layer 225 and over the substrate 200 and the device 210. Alternatively, the additives may be provided to the second material layer 230 by doping, thermal bake-in, or other non-mixture process. The coated substrate 200 and the device 210 with the raw material of the second material layer 230 are then cured in a furnace or oven to remove moisture therein. The selection of the first material layer 225 and the second material layer 230 depends on desired mechanical and electrical characteristics of the packaged device. Relations between exemplary dopant concentrations and thermal conductivities shown in Tables I-III are merely provided as examples. One skilled in the art is capable of modifying the conductive fillers 235 and their concentrations to form the desired package structure.

The two-layer packaged device shown in FIG. 2B provides the desired heat dissipation function primarily through the second material layer 230. In this embodiment, the first material layer 225 helps to protect or isolate the device 210 from diffusion of the conductive fillers 235 from the second material layer 230. The use of the two-layer structure thus provides the desired thermal and electrical properties of the packaged device. In some embodiments, the second material layer 230 has the thermal conductivity higher than about 0.8 W/mK corresponding to a desired dopant concentration of conductive filler 235.

In other embodiments, the second material layer 230 comprises an electron-conjugation polymer. The electron-conjugation includes, for example, π-electron conjugation. Monomers that are used to synthesize such conjugation polymers are aromatic or contain multiple carbon-carbon double bonds. In embodiments, the second material layer 230 with the electron conjugation has thermal conductivity higher than about 0.8 W/mK.

As shown in FIG. 2B, the second material layer 230 is disposed over the first material layer 225, encapsulating the device 210. In preferred embodiments, the second material layer 230 has a thermal conductivity higher than that of the first material layer 225. Due to its high thermal conductivity, the second material layer 230 efficiently disperses heat generated from the operation of the device 210 to the surrounding environment or a heatspreader layer or fan (not shown). As set forth above, the thermal conductivity of the first material layer 225 is preferably less than or equal to about 0.3 W/mK, and the thermal conductivity of the second material layer 230 is preferably more than about 0.8 W/mK. In some embodiments, however, the first material layer 225 and the second material layer 230 substantially have the same thermal conductivity as long as the heat dissipation of the packaged device meets the desired requirements. One skilled in the art will understand how to modify the thermal conductivities of the first material layer 225 and the second material layer 230 as needed based on these teachings.

In one embodiment, the first material layer 225, in addition to transferring heat to the second material layer 230, serves as an electrical isolation layer which is able to substantially prevent the conductive fillers 235 from diffusing into the first material layer 225 to such a level that would interfere with wires 220. In this embodiment, the first material layer 225 substantially prevents contact between the conductive fillers 235 and the conductive wires 220 resulting from the diffusion of the conductive fillers 235 into the first material layer 225. Any thermal conductive fillers 227 in the first material layer 225 are provided in low enough concentrations so as to not interfere with the operation of the device 210. In some embodiments, the first material layer 225 has an electrical resistivity higher than that of the second material layer 230 such that it provides effective thermal transfer without interfering with the operation of the device 210. In other embodiments, the first material layer 225 and the second material layer 230 substantially have the same electrical resistivity as long as the dopants within the first material layer 225 and the second material layer 230 do not affect the electrical performance of the packaged device. One skilled in the art thus is able to modify the electrical resistivities of the first material layer 225 and the second material layer 230 according to these exemplary embodiments.

The first material layer 225 may also serve as a buffer layer between the device 210 and the second material layer 230 to eliminate cracking resulting from differences between the thermal expansion coefficient of the device 210 and the second material layer 230. In addition, the conductive fillers 235 added in the second material layer 230 substantially do not affect the adhesion between the second material layer 230 and the first material layer 220. Any adhesion concerns can be substantially eliminated if both of the first material layer 220 and the second material layer 230 have material properties similar to each other. For example, the first material layer 220 and the second material layer 230 can be the same material, such as epoxy layers.

In some embodiments, the structure of FIG. 2B also contributes to the mechanical performance of the final package. Because the first material layer 225 and the second material layer 230 encapsulate the device 210 and contact the substrate 200, the physical properties of the first material layer 225 and the second material layer 230 affect how thermal stresses are translated and manifested in the final package. Thus, the physical properties of the structure shown in FIG. 2B provide an opportunity to help control the performance of the final package.

In some embodiments with metal powder additives 235, the second material layer 230 shields a particles and prevents soft error to the device 210 such as occur within Dynamic Random Access Memory (DRAM) devices. These electrically conductive additives help shield the device 210 from radiation. The electrical performance of the device 210 is thus maintained.

In some embodiments, more than two material layers encapsulate the device 210. In these embodiments, the first material layer 225, which is at the bottom of the multi-layer structure, is able to prevent the conductive fillers 235 from diffusing to the device 210. The other material layers over the first material layer 225 are adapted to perform the additional mechanical, heat transfer and/or electrical isolation functions described above. One of ordinary skill in the art will be able to select the desired material layers to provide devices with the various desired characteristics.

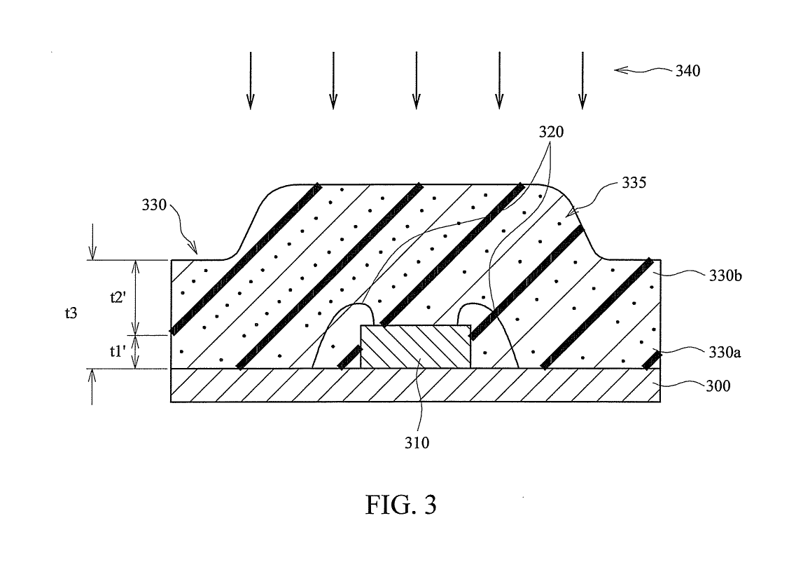

FIG. 3 is a schematic cross-sectional view of a packaged device according to another exemplary embodiment. The packaged device comprises a substrate 300, a device 310 and a material layer 330. The device 310 is disposed on the substrate 300. The material layer 330 is formed over the device 310 and the substrate 300. The material layer 330 comprises at least two portions. The first portion 330a of the material layer 330 is adjacent to the device 310, and the second portion 330b of the material layer 330 is adjacent to the first portion 330a of the material layer 330 and more proximate to the top surface thereof. The device 310 is electrically coupled to the substrate 300 by a wire-bonding method or a flip-chip process. In this embodiment, the device 310 is coupled to the substrate through conductive wires 320. Exemplary materials of the substrate 300, the device 310 and the conductive wires 320 are described above in connection with FIGS. 2A and 2B.

In this embodiment, the first portion 330a and the second portion 330b of the material layer 330 comprise the same material and form a single layer. The material layer 330 is formed over the device 310 by a spin-coating method or a molding method. The coated substrate 300 and the device 310 with the material layer 330 are then cured in a furnace or oven to remove moisture therein.

The second portion 330b of the material layer 330 includes the conductive fillers 335 and has a thermal conductivity higher than a thermal conductivity of the first portion 330a of the material layer 330. The thermal conductivity of the second portion 330b can be increased by adding conductive fillers to the material layer 330, such as metal powders, ceramic fillers, inorganic nanocomposites or other dopants which are adapted to enhance the thermal conductivity of the second portion 330b. In a preferred embodiment, metal powders, ceramic fillers, and inorganic nanocomposites can be added into the matrix of the material layer 230 by a doping process. The doping process can be, for example, ion implantation 340 as shown in FIG. 3. The depth of the implantation can be controlled using parameters familiar to those in the art, such as implantation power. The doping process can also be a thermal-driving process where a material with the conductive fillers 335 is deposited on the top surface of the material layer 330 and then the conductive fillers 335 are thermally driven into the material layer 330 to a desired depth, which is controlled by, for example, time, temperature, and/or the thickness of the deposited doping layer. The distribution of the dopants can be gradually or abruptly changed within the material layer 330 as long as the package structure is able to perform the desired thermal dissipation purpose. In some embodiments, the thickness “t3” of the material layer 330 is from about 0.3 mm to about 2 mm as shown in FIG. 3. The first portion 330a has a thickness t1′ from about 10 μm to about 200 μm. The second portion 330b has a thickness t2′. The thicknesses t1′ and t2′ are adjustable, as long as the material layer 330 can efficiently dissipate the heat of the device 310 and the conductive fillers 335 do not deteriorate the electrical performance of the device 310.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

What is claimed is:

1. A packaged device, comprising:
at least one device disposed on a substrate; and
a material layer encapsulating the device and covering at least a portion of the substrate, wherein the material layer comprises at least a first portion adjacent to the device and a second portion over the first portion, the second portion having a thermal conductivity higher than a thermal conductivity of the first portion.

2. The packaged device of claim 1, wherein the first portion of the material layer comprises a material different from a material of the second portion of the material layer.

3. The packaged device of claim 1, wherein the first portion of the material layer comprises an electrical isolation layer.

4. The packaged device of claim 1, wherein the first portion of the material layer comprises a thermalset polymer with a glass transition temperature (Tg) higher than about 200° C.

5. The packaged device of claim 4, wherein the thermalset polymer comprises at least one selected from the group consisting of Acrylonitrile-Butadiene-Styrene Terpolymer (ABS), Polyamide (PA), Poly(methyl methacrylate) (PMMA), Polycarbonates (PC), Polyethylene terephthalate (PET), Polybutylece terephthalate (PBT) and polyvinyl chloride (PVC).

6. The packaged device of claim 1, wherein the thermal conductivity of the first portion of the material layer is less than or equal to about 0.3 W/mK, and the thermal conductivity of the second portion of the material layer is higher than about 0.8 W/mK.

7. The packaged device of claim 1, wherein the second portion of the material layer comprises conductive filler.

8. The packaged device of claim 7, wherein the conductive filler comprises at least one of a metallic powder, a ceramic filler and an inorganic nanocomposite.

9. The packaged device of claim 8, wherein the ceramic filler comprises at least one of silica, quartz, boron nitride and aluminum nitride.

10. The packaged device of claim 8, wherein the inorganic nanocomposite comprises at least one of laminar clay and nanotube.

11. The packaged device of claim 1, wherein the second portion of the material layer comprises electron conjugation with an inherent thermal conductivity higher than about 0.8 W/mK.

12. The packaged device of claim 1, wherein the second portion of the material layer comprises a thermalset polymer with a glass transition temperature (Tg) higher than about 200° C.

13. The packaged device of claim 12, wherein the thermalset polymer comprises at least one selected from the group consisting of Acrylonitrile-Butadiene-Styrene Terpolymer (ABS), Polyamide (PA), Poly(methyl methacrylate) (PMMA), Polycarbonates (PC), Polyethylene terephthalate (PET), Polybutylece terephthalate (PBT) and polyvinyl chloride (PVC).

14. A packaged device, comprising:
at least one device disposed on a substrate;
a first thermalset polymer layer encapsulating the device; and
at least one second thermalset polymer layer formed over the first thermalset polymer layer to encapsulate the device, wherein a thermal conductivity of the first thermalset polymer layer is less than a thermal conductivity of the second thermalset polymer layer.

15. The packaged device of claim 14, wherein the second thermalset polymer layer comprises at least one of a metallic powder, a ceramic filler and an inorganic nanocomposite.

16. The packaged device of claim 15, wherein the conductive filler comprises a metal element.

17. The packaged device of claim 15, wherein the ceramic filler comprises at least one of silica, quartz, boron nitride and aluminum nitride.

18. The packaged device of claim 15, wherein the inorganic nanocomposite comprises at least one of laminar clay and nanotube.

19. The packaged device of claim 14, wherein the second thermalset polymer layer comprises electron conjugation with an inherent thermal conductivity higher than about 0.8 W/mK.

20. The packaged device of claim 14, wherein a thermal conductivity of the first thermalset polymer layer is less than or equal to about 0.3 W/mK and the second thermalset polymer layer is higher first thermalset polymer layer than about 0.8 W/mK.

21. A packaged device, comprising:
at least one device disposed on a substrate;
a first epoxy layer encapsulating the device; and
at least one second epoxy layer formed over the first epoxy layer to encapsulate the device, wherein a thermal conductivity of the first epoxy layer is less than a thermal conductivity of the second epoxy layer, the thermal conductivity of the second epoxy layer is higher than about 0.8 W/mK, and the second epoxy layer comprises at least one of silica, quartz, boron nitride and aluminum nitride.
